(19) United States
(12) Patent Application Publication
(10) Pub. No.: US 2024/0162305 A1
(43) Pub. Date: May 16, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Kodai OZAWA, Tokyo (JP); Sho NAKANISHI, Tokyo (JP)

(21) Appl. No.: 18/054,996

(22) Filed: Nov. 14, 2022

(51) Int. Cl. H01L 29/40; H01L 29/06

(52) U.S. Cl. CPC H01L 29/404; H01L 29/0623; H01L 29/401

(57) ABSTRACT

A manufacturing method of a semiconductor device includes: (a) preparing a semiconductor substrate of a first conductivity type having an upper surface and a lower surface; (b) after the (a), forming an interlayer dielectric film on the upper surface of the semiconductor substrate; (c) after the (b), forming a base film on the interlayer dielectric film; (d) after the (c), forming a first conductive film on the base film; (e) after the (d), patterning the first conductive film to form a first wiring and a second wiring next to the first wiring; and (f) after the (e), removing the base film located between the first wiring and the second wiring. A material constituting the base film is different from a material constituting the first conductive film.

### BACKGROUND

The present disclosure relates to a semiconductor device and a method of manufacturing the same, and more particularly, to the semiconductor device including a wiring on an interlayer dielectric film and the method of manufacturing the same.

In a semiconductor device such as a semiconductor chip, in order to relax a high electric field generated in a cell region and improve a withstand voltage, a contrivance is applied to an outer periphery of the cell region.

There are disclosed techniques listed below.
[Patent Document 1] Japanese Unexamined Patent Application Publication No. 2018-206842

For example, Patent Document 1 discloses a cell region in which a semiconductor device such as IGBT (Insulated Gate Bipolar Transistor) is formed and an outer peripheral region surrounding the cell region. A p-type field limiting ring region is formed in a semiconductor substrate in an outer peripheral region, and a wiring called a field plate is formed annularly on the field limiting ring region.

### SUMMARY

In the outer peripheral region, a plurality of wirings surround the cell region as field plates, but if a residue of wirings exists between the respective wiring, this residue functions as a leak path, and the withstand voltage may decrease.

FIG. 22 to FIG. 24 show a manufacturing process of a semiconductor device of the first examined example studied by the present inventors. Here, manufacturing processes are shown in which an interlayer dielectric film IL is formed on a semiconductor substrate SUB and a wiring M1 is formed on the interlayer dielectric film IL.

As shown in FIG. 22, a conductive film CF1 is formed on the interlayer dielectric film IL by a sputtering method. The conductive film CF1 is formed of, for example, an aluminum alloy (AlSi) that an additive such as silicon (Si) is added to aluminum (Al). A hole CH reaching the semiconductor substrate SUB is formed in the interlayer dielectric film IL, and the conductive film CF1 is formed so as to fill the inside of the hole CH. Here, a silicon precipitate 10 may be formed in the conductive film CF1.

As shown in FIG. 23, a wiring M1 is formed by patterning the conductive film CF1 by an anisotropic etching process. At this time, when the conductive film CF1 contains the precipitate 10, the precipitate 10 functions as an etching mask, and a part of the conductive film CF1 is left as the residue 20. Here, the residue 20 is formed of AlSi. As described above, since the residue 20 may function as a leak path, the residue 20 needs to be removed.

As shown in FIG. 24, the residue 20 can be removed by performing over-etching in order to remove the residue 20, but the thickness of the interlayer dielectric film IL around the residue 20 is reduced. Therefore, a defect related to reliability, such as deterioration of insulation resistance, may occur.

The wiring M1 is formed in the same manufacturing process as the pad electrode for bonding the bonding wire, but in recent years, the pad electrode (wiring M1) has been thickened in order to relax the stresses at the time of bonding the bonding wire and the pad electrode. Therefore, the thickness of the conductive film CF1 serving as the base of wiring M1 needs to be increased, and accordingly, there is a high possibility that the precipitate 10 is generated, and there is a high possibility that the residue 20 is generated.

As a countermeasure against these problems, it is conceivable to increase the thickness of the interlayer dielectric film IL in advance in view of the over-etching quantity for removing the residue 20. However, in such case, the aspect ratio becomes higher when the conductive film CF1 is filled inside the hole CH, and there is a high possibility that the conductive film CF1 will be poorly filled.

In addition, the generation of the precipitate 10 is caused by various conditions such as sputtering conditions, a target used for sputtering, and an interface condition of the base film. Therefore, since the size and the quantity of the precipitate 10 are not constant for each position, the size and the quantity of the residue 20 also differ for each position. Therefore, it is difficult to quantify the quantity of over-etching because the optimum quantity of over-etching for completely removing the residue 20 varies from wafer to wafer.

The main purpose of the present application is to improve the reliability of the semiconductor device by providing a technique capable of removing the residue 20 and sufficiently suppressing a decrease in the thickness of the interlayer dielectric film IL. Other purpose and novel features will become apparent from the description of this specification and the accompanying drawings.

The typical ones of the embodiments disclosed in the present application will be briefly described as follows.

A manufacturing method of a semiconductor device according to one embodiment includes: (a) preparing a semiconductor substrate of a first conductivity type having an upper surface and a lower surface; (b) after the (a), forming an interlayer dielectric film on the upper surface of the semiconductor substrate; (c) after the (b), forming a base film on the interlayer dielectric film; (d) after the (c), forming a first conductive film on the base film; (e) after the (d), patterning the first conductive film to form a first wiring and a second wiring next to the first wiring; and (f) after the (e), removing the base film located between the first wiring and the second wiring. A material constituting the base film is different from a material constituting the first conductive film.

A semiconductor device according to one embodiment includes: a semiconductor substrate of a first conductivity type having an upper surface and a lower surface, an interlayer dielectric film formed on the upper surface of the semiconductor substrate, a protective film selectively formed on the interlayer dielectric film, a first hole and a second hole each formed in the interlayer dielectric film so as to reach the semiconductor substrate at a position not overlapping with the protective film in plan view, a first wiring formed on the interlayer dielectric film and the protective film so as to fill the inside of the first hole, and a second wiring formed on the interlayer dielectric film and the protective film so as to fill the inside of the second hole, the second wiring being next to the first wiring. An end portion of the first wiring and an end portion of the second wiring are located on the protective film, the protective film covers the interlayer dielectric film located between the first wiring and the second wiring, and a material constituting the protective film is different from a material constituting each of the first wiring, the second wiring and the interlayer dielectric film.

### BRIEF DESCRIPTION OF THE DRAWINGS

FIG. 1 is a plan view showing the semiconductor device in the first embodiment.

FIG. 2 is a cross-sectional view showing the semiconductor device in the first embodiment.

FIG. 3 is a cross-sectional view showing a manufacturing process of the semiconductor device in the first embodiment.

FIG. 4 is a cross-sectional view showing a manufacturing process of the semiconductor device following FIG. 3.

FIG. 5 is a cross-sectional view showing a manufacturing process of the semiconductor device following FIG. 4.

FIG. 6 is a cross-sectional view showing a manufacturing process of the semiconductor device following FIG. 5.

FIG. 7 is a cross-sectional view showing a manufacturing process of the semiconductor device following FIG. 6.

FIG. 8 is a cross-sectional view showing a manufacturing process of the semiconductor device following FIG. 7.

FIG. 9 is a cross-sectional view showing the semiconductor device in the second embodiment.

FIG. 10 is a cross-sectional view showing a manufacturing process of the semiconductor device in the second embodiment.

FIG. 11 is a cross-sectional view showing a manufacturing process of the semiconductor device following FIG. 10.

FIG. 12 is a cross-sectional view showing a manufacturing process of the semiconductor device following FIG. 11.

FIG. 13 is a cross-sectional view showing a manufacturing process of the semiconductor device following FIG. 12.

FIG. 14 is a cross-sectional view showing a manufacturing process of the semiconductor device following FIG. 13.

FIG. 15 is a cross-sectional view showing the semiconductor device in the third embodiment.

FIG. 16 is a cross-sectional view showing a manufacturing process of the semiconductor device in the third embodiment.

FIG. 17 is a cross-sectional view showing a manufacturing process of the semiconductor device following FIG. 16.

FIG. 18 is a cross-sectional view showing a manufacturing process of the semiconductor device following FIG. 17.

FIG. 19 is a cross-sectional view showing a manufacturing process of the semiconductor device following FIG. 18.

FIG. 20 is a cross-sectional view showing a manufacturing process of the semiconductor device following FIG. 19.

FIG. 21 is a cross-sectional view showing a manufacturing process of the semiconductor device following FIG. 20.

FIG. 22 is a cross-sectional view showing a manufacturing process of the semiconductor device in a 1 examined example.

FIG. 23 is a cross-sectional view showing a manufacturing process of the semiconductor device following FIG. 22.

FIG. 24 is a cross-sectional view showing a manufacturing process of the semiconductor device following FIG. 23.

FIG. 25 is a cross-sectional view showing the semiconductor device in the second examined example.

FIG. 26 is a cross-sectional view showing the semiconductor device in the third examined example.

### DETAILED DESCRIPTION

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

In addition, the X direction, the Y direction, and the Z direction described in the present application intersect each other and are orthogonal to each other. In the present application, the Z direction is described as a vertical direction, a height direction, or a thickness direction of a certain structure. In addition, the expression “plan view” used in the present application means that the plane formed by the X direction and the Y direction is a “plane” and the “plane” is viewed from the Z direction.

### First Embodiment

### Structure of Semiconductor Device

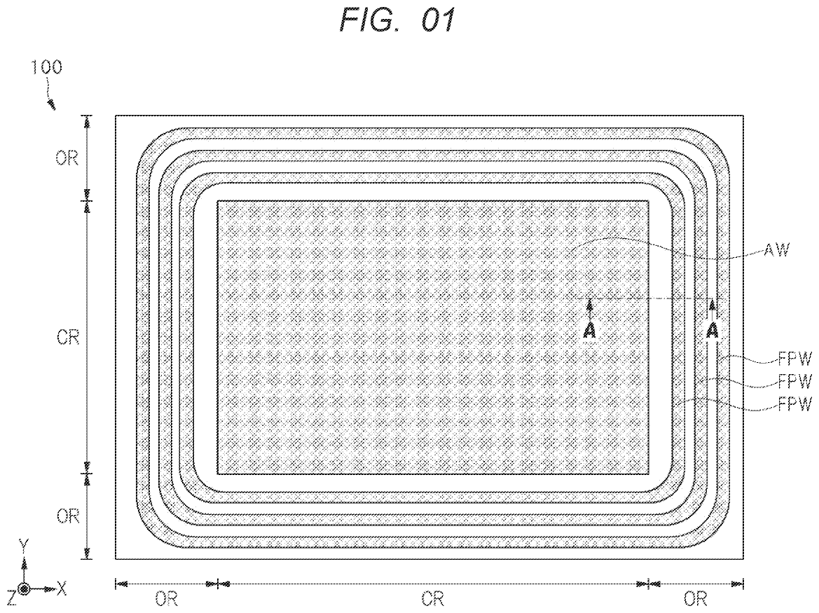

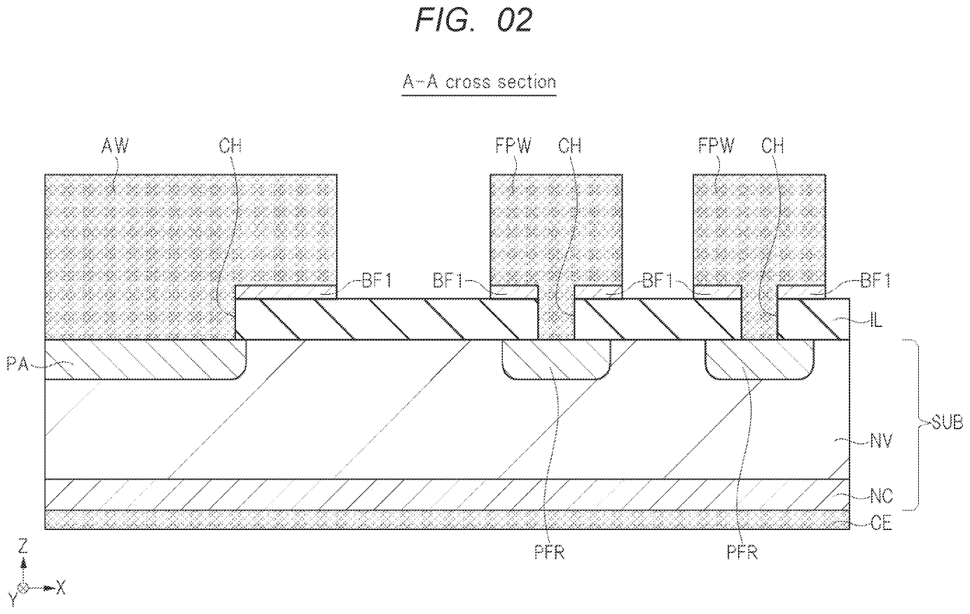

The structure of the semiconductor device 100 in the first embodiment will be described below with reference to FIG. 1 and FIG. 2. FIG. 1 is a plan view showing a semiconductor chip which is the semiconductor device 100. FIG. 2 is a cross-sectional view along line A-A shown in FIG. 1.

As shown in FIG. 1, the semiconductor device 100 includes a cell region CR in which a semiconductor element is formed, and an outer peripheral region OR surrounding the cell region CR in plan view. In the first embodiment, the semiconductor element is a diode, and an anode wiring AW is formed in the cell region CR. In the outer peripheral region OR, a plurality of field plate wirings FPW are formed so as to surround the anode wiring AW in the cell region CR in plan view.

The field plate wiring FPW closest to the cell region CR is surrounded by another field plate wiring FPW in plan view. Each of the field plate wirings FPW is annularly formed. Although three field plate wirings FPW are exemplified here, the number of field plate wirings FPW may be at least one, and may be four or more.

An external connecting member such as a bonding wire or a clip (copper plate) is connected to the anode wiring AW, so that the semiconductor device 100 is electrically connected to another semiconductor chip, a wiring substrate, or the like.

A cross-sectional structure of the semiconductor device 100 will be described below with reference to FIG. 2. First, a cross-sectional structure in the cell region CR will be described, and then a cross-sectional structure in the outer peripheral region OR will be described.

As shown in FIG. 2, the semiconductor device 100 includes an n-type semiconductor substrate SUB having an upper surface and a lower surface. The semiconductor substrate SUB has a low concentration n-type drift region NV. Here, the n-type semiconductor substrate SUB itself constitute the drift region NV. Note that the drift region NV may be an n-type semiconductor layer grown on an n-type silicon substrate while introducing phosphorus (P) by an epitaxial growth method. In the present application, a laminated body formed of such n-type silicon substrate and n-type semiconductor layer is also described as being the semiconductor substrate SUB.

On the lower surface side of the semiconductor substrate SUB, an n-type cathode region NC is formed in the semiconductor substrate SUB. The cathode region NC has a higher impurity concentration than the drift region NV. A cathode electrode CE is formed on the lower surface of the semiconductor substrate SUB. The cathode electrode CE is formed of, for example, a single-layer metal film such as an aluminum film, a titanium film, a nickel film, a gold film or a silver film, or a laminated film containing these metal films as appropriate. The cathode region NC and the cathode electrode CE are formed over the cell region CR and the outer peripheral region OR. The cathode potential is supplied from the cathode electrode CE to the semiconductor substrate SUB (cathode region NC, drift region NV).

In the upper surface side of the semiconductor substrate SUB, a p-type anode region CR is formed in the semiconductor substrate SUB in the cell region CR. An interlayer dielectric film IL is formed on the upper surface of the semiconductor substrate SUB. The interlayer dielectric film IL is formed of, for example, a silicon oxide film. The thickness of the interlayer dielectric film IL is, for example, 600 nm or more and 2000 nm or less. The interlayer dielectric film IL may be a laminated film of a thin silicon oxide film and a thick silicon oxide film containing phosphorus (PSG: Phospho Silicate Glass film). The interlayer dielectric film IL may be a laminated film of a thin silicon oxide film and a thick silicon oxide film containing boron and phosphorus (BPSG: Boro Phospho Silicate Glass film).

A hole CH reaching the semiconductor substrate SUB (anode region PA) is formed in the interlayer dielectric film IL. An anode wiring AW is formed on the interlayer dielectric film IL so as to fill the inside of the hole CH. The anode wiring AW is electrically connected to the anode region PA and supplies an anode potential to the anode region PA.

Outside the hole CH, a base film BF1 is formed between the anode wiring AW and the interlayer dielectric film IL. The base film BF1 is, for example, a polycrystalline silicon film or a silicon nitride film. The thickness of the base film BF1 is smaller than the thickness of the interlayer dielectric film IL, for example, greater than or equal to 100 nm and less than or equal to 600 nm.

The main feature of the first embodiment is that the base film BF1 is formed, and such a feature will be described in detail in a manufacturing method of the semiconductor device described later.

Hereinafter, the cross-sectional structure of the outer peripheral region OR will be described.

On the upper surface side of the semiconductor substrate, a plurality of p-type field limiting regions PFR are formed in the semiconductor substrate SUB in the outer peripheral region OR. The interlayer dielectric film IL is formed on the upper surface of the semiconductor substrate SUB. The hole CH reaching the semiconductor substrate SUB (field limiting region PFR) is formed in the interlayer dielectric film IL.

A field plate wiring FPW is formed on the interlayer dielectric film IL so as to fill the inside of the hole CH. The field plate wiring FPW is electrically connected to the field limiting region PFR. The field plate wiring FPW and the field limiting region PFR are not connected to the anode wiring AW and the external connecting member, and are in an electrically floating state.

The plurality of field plate wirings FPW are next to each other. In addition, the field plate wiring FPW located on the innermost inner periphery among the plurality of field plate wirings FPW and the anode wiring AW are next to each other.

Further, one field limiting region PFR is formed under one field plate wiring FPW. Each of the field limiting regions PFR surrounds the cell region CR (anode region PA) along each field plate wiring FPW shown in FIG. 1. That is, each of the field limiting regions PFR is formed in a circular shape. The field limiting region PFR closest to the cell region CR is surrounded by another field limiting region PFR in plan view.

Also in the outer peripheral region OR, the base film BF1 is formed between the field plate wiring FPW and the interlayer dielectric film IL outside the hole CH. In the first embodiment, between the field plate wirings FPW and between the anode wiring AW and the field plate wiring FPW, the base film BF1 is not formed, and the interlayer dielectric film IL is exposed.

Since the field limiting region PFR is provided, the depletion layer can be extended from the cell region CR toward the outer peripheral region OR, so that a high electric field generated in accordance with a high voltage applied to the cell region CR can be relaxed. Further, in plan view, the field plate wiring FPW covers not only the field limiting region PFR but also the boundary between the field limiting region PFR and the drift region NV. Accordingly, the electric field generated at the boundary is also relaxed.

The anode wiring AW and the field plate wiring FPW are wirings formed in the same manufacturing process, and are formed of, for example, an aluminum alloy that an additive is added to aluminum (Al). The additive is, for example, silicon (Si), and the content thereof is 0.5% or more and 1.0% or less. The additive may be copper (Cu) or both silicon (Si) and copper (Cu). The thickness of each of the anode wiring AW and the field plate wiring FPW is, for example, 2.0 μm or more and 7.0 μm or less.

The anode wiring AW and the field plate wiring FPW may be a laminated film of a barrier metal film and the aluminum alloy formed on the barrier metal. The barrier metal film is, for example, a titanium film or a titanium nitride film, or a laminated film obtained by laminating these films as appropriate.

### Manufacturing Method of Semiconductor Device

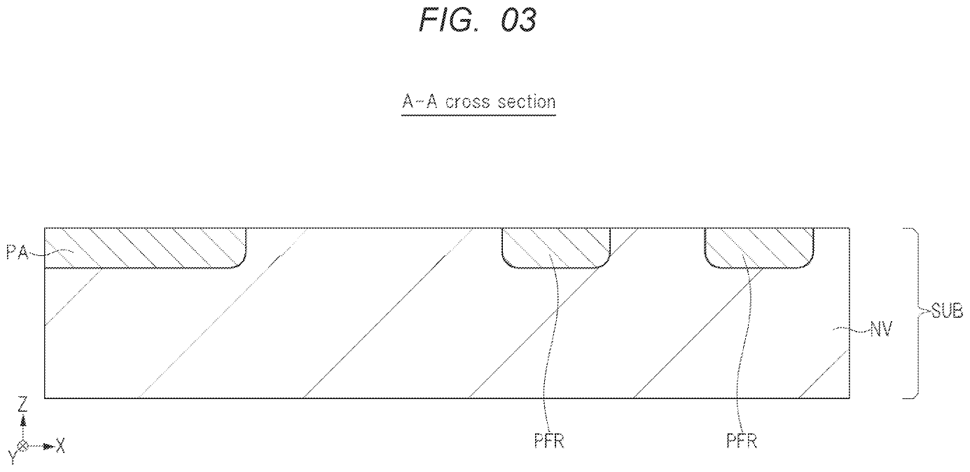

The respective manufacturing processes included in the manufacturing method of the semiconductor device 100 in the first embodiment will be described below with reference to FIG. 3 to FIG. 8.

As shown in FIG. 3, first, the n-type semiconductor substrate SUB having an upper surface and a lower surface is prepared. As described above, the n-type semiconductor substrate SUB itself constitute the drift region NV, but the drift region NV may be an n-type semiconductor layer grown on the n-type silicon substrate while introducing phosphorus (P) by epitaxial growth method.

Next, on the upper surface side of the semiconductor substrate SUB, by selectively introducing, for example, boron (B) into the semiconductor substrate SUB by a photolithography technique and an ion-implantation method, a p-type anode region PA is formed in the semiconductor substrate SUB in the cell region CR and a p-type field limiting region PFR is formed in the semiconductor substrate SUB in the outer peripheral region OR. Thereafter, the semiconductor substrate SUB is subjected to a heat treatment to diffuse impurities included in the anode region PA and the field limiting region PFR.

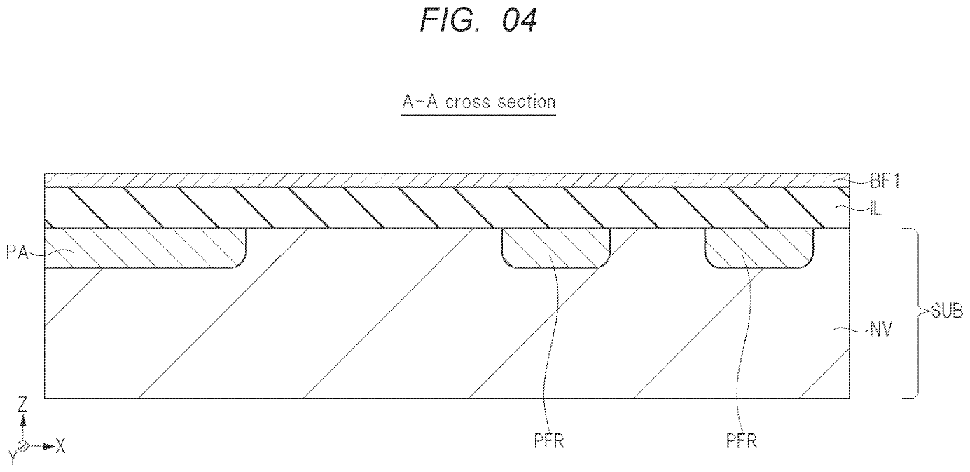

As shown in FIG. 4, first, the interlayer dielectric film IL is formed on the upper surface of the semiconductor substrate SUB in the cell region CR and the outer peripheral region OR by, for example, a CVD (Chemical Vapor Deposition) method. The interlayer dielectric film IL is formed of, for example, a silicon oxide film. The interlayer dielectric film IL may be a laminated film of a thin silicon oxide film formed by a CVD method and a thick PSG film or BPSG film formed by a coating method. Next, a base film BF1 is formed on the interlayer dielectric film IL in the cell region CR and the outer peripheral region OR by, for example, a CVD method.

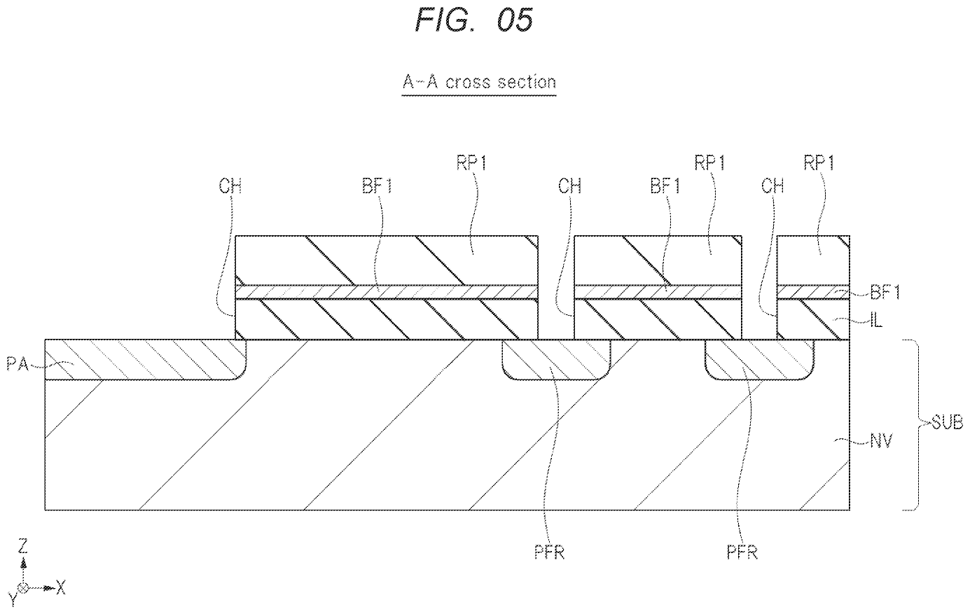

As shown in FIG. 5, first, a resist pattern RP1 is formed on the interlayer dielectric film IL. Next, by performing an anisotropic etching process using the resist pattern RP1 as a mask, a plurality of holes CH reaching the semiconductor substrate SUB are formed in the base film BF1 and the interlayer dielectric film IL. In the cell region CR, the hole CH reaches the anode region PA. In the outer peripheral region OR, the hole CH reaches the field limiting region PFR. Thereafter, the resist pattern RP1 is removed by an asking process.

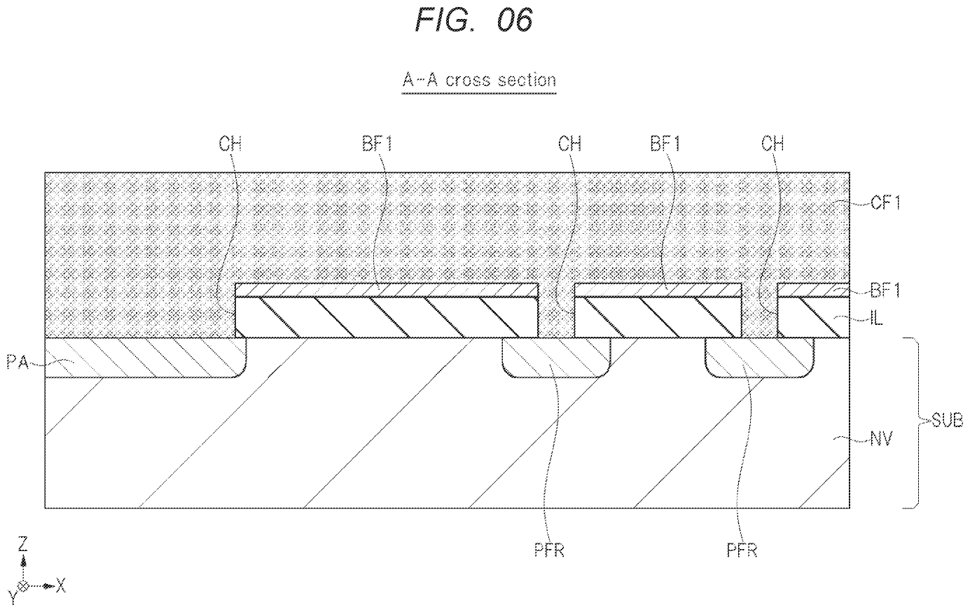

As shown in FIG. 6, a conductive film CF1 is formed on the base film BF1 by a sputtering method so as to fill the insides of the plurality of holes CH. The conductive film CF1 is formed of the above-described aluminum alloy. The conductive film CF1 may be a laminated film of the above-described barrier metal film and an aluminum alloy.

In the first embodiment, a diode is formed in the cell region CR, and an additive contained in the aluminum alloy is precipitated at the interface between the conductive film CF1 and the anode region PA. For example, when the aluminum alloy is an AlSi film, Si is precipitated at the interface (AlSi/Si interface).

According to studies conducted by the inventors of the present application, it was found that by setting the temperature in the above-mentioned sputtering method to 150° C. or less, the size and the number of the precipitate due to the above-mentioned additive can be reduced. On the other hand, it has also been found that the size and quantity of the precipitate due to the additive tend to be increased in aluminum alloy which is to be wiring. That is, it was found that, instead of being able to reduce the precipitate in the diode, the residue tends to remain between the respective wiring. However, the size and quantity of the precipitate at the interface between the conductive film CF1 and the anode region PA and the precipitate in the conductive film CF1 are not determined only by the temperature in the sputtering method described above, and vary depending on the target used in the sputtering method, the interface condition of the base film, and the heat treatment condition after forming the anode wiring AW and the field plate wiring FPW, and the like.

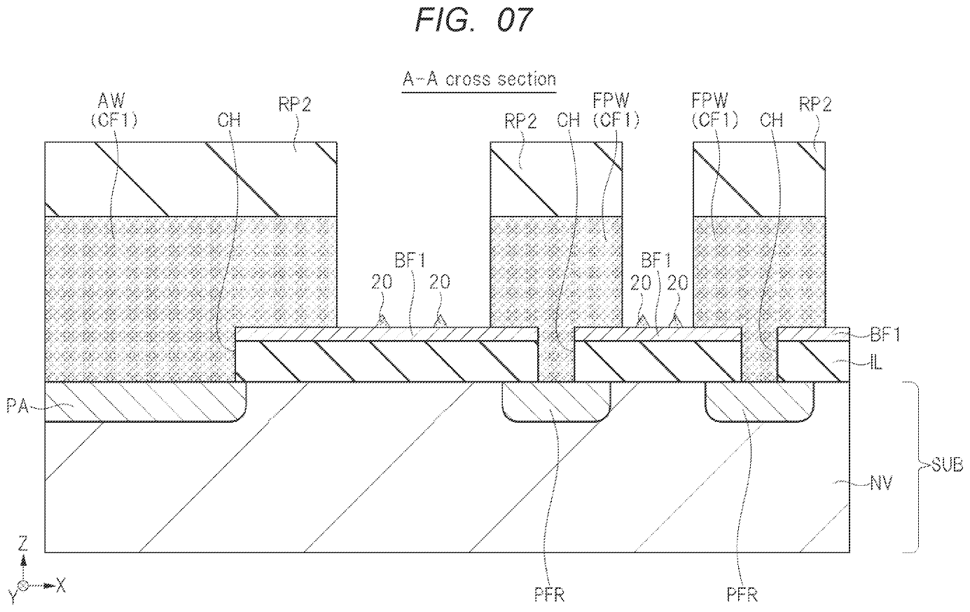

As shown in FIG. 7, first, a resist pattern RP2 is formed on the conductive film CF1. Next, the conductive film CF1 is patterned by performing an anisotropic etching process using the resist pattern RP2 as a mask. In the anisotropic etching process, for example, chlorine (Cl₂) gases are used. As a result, a part of the conductive film CF1 is removed, an anode wiring AW is formed in the cell region CR, and a plurality of field plate wirings FPW are formed in the outer peripheral region OR.

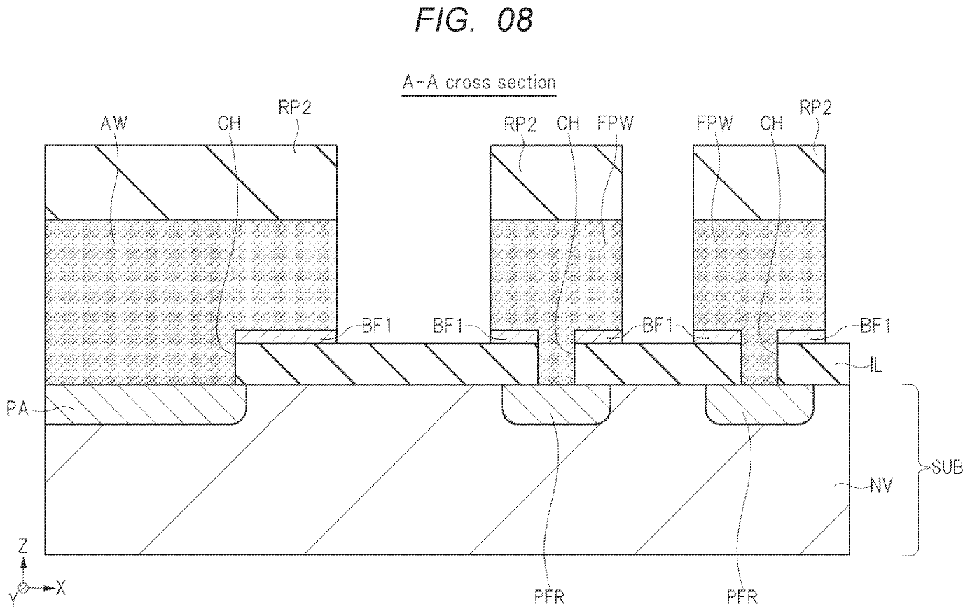

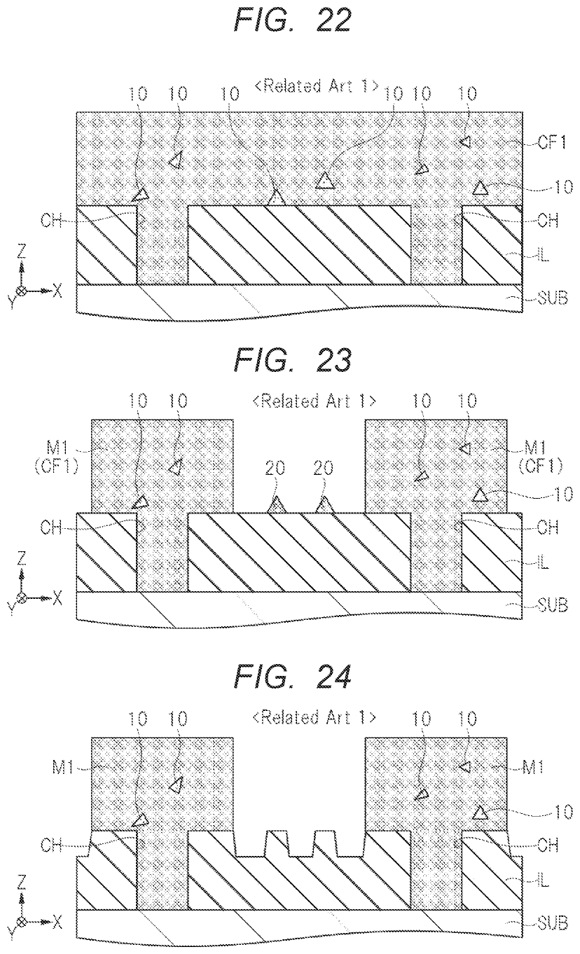

During this patterning, as described with reference to FIG. 22 to FIG. 24, a residue 20 may be left on the base film BF1 due to the precipitate 10 in the conductive film CF1. The residue 20 is formed of the same material as the material constituting the conductive film CF1. To remove this residue 20, the manufacturing process of FIG. 8 is performed.

As shown in FIG. 8, the base film BF1 located between wirings is removed by performing an isotropic etching process using the resist pattern RP2 as a mask. That is, by the isotropic etching process, the underlying film BF1 located between the field plate wirings FPW and between the anode wiring AW and the field plate wiring FPW are removed. At this time, the residue 20 formed on the base film BF1 is not directly removed by the isotropic etching process, but the residue 20 is indirectly removed as the base film BF1 is removed. Thereafter, the resist pattern RP2 is removed by an asking process.

The material constituting the base film BF1 is different from the material constituting each of the interlayer dielectric film IL and the conductive film CF1 (anode wiring AW, field plate wiring FPW) in order to ensure a satisfactory selectivity in the isotropic etching process. As described above, the base film BF1 is a polycrystalline silicon film or a silicon nitride film. The interlayer dielectric film in contact with the base film BF1 is a silicon oxide film, and the conductive film CF1 in contact with the base film BF1 is formed of an aluminum alloy.

When the base film BF1 is a polycrystalline silicon film, for example, sulfur hexafluoride (SF₆) or chlorine tetrafluoride (ClF₄) is used in the isotropic etching process. When the base film BF1 is a silicon nitride film, for example, an aqueous solution containing phosphoric acid is used in the isotropic etching process.

Thereafter, the structure of FIG. 2 is obtained through the following manufacturing process. First, an n-type cathode region NC is formed in the lower surface of the semiconductor substrate SUB by performing an ion-implantation from the lower surface side of the semiconductor substrate SUB. After this ion-implantation, a laser annealing is performed to activate impurities contained in the cathode region NC. Next, a cathode electrode CE is formed on the lower surface of the semiconductor substrate SUB by, for example, a sputtering method.

### Main Features of First Embodiment

In the first embodiment, the thickness of the anode wiring AW is increased in order to relax stresses at the time of adhesion between an external connecting member such as a bonding wire and the anode wiring AW. Therefore, the thickness of the conductive film CF1 serving as a base of wiring M1 is set to, for example, 2.0 μm or more and 7.0 μm or less. However, the number of precipitates 10 increases accordingly, and the possibility that the residue 20 is generated also increases.

In addition, the generation of the precipitate 10 is caused by various conditions such as sputtering conditions, a target used for sputtering, and an interface condition of the base film. Therefore, since the size and the quantity of the precipitate 10 are not constant for each position, the size and the quantity of the residue 20 also differ for each position.

In the first embodiment, even if the residue 20 is generated, the residue 20 is formed on the base film BF1. Therefore, in the manufacturing process of FIG. 8, the residue 20 is indirectly removed as the base film BF1 is removed. The base film BF1 is removed by an isotropic etching process that ensures adequate selectivity. Therefore, in order to remove the residue 20, the interlayer dielectric film IL does not need to be over-etched, so that it is possible to sufficiently suppress the thickness of the interlayer dielectric film IL from decreasing. In addition, since the thickness of the interlayer dielectric film IL does not need to be increased in advance in view of the quantity of over-etching, there is no problem that the aspect ratio increases when the conductive film CF1 is filled inside the hole CH. Therefore, according to the first embodiment, the reliability of the semiconductor device 100 can be improved.

It should be noted that the thickness of the base film BF1 may be any thickness as long as a sufficient selectivity can be ensured during the isotropic etching process. If the thickness of the base film BF1 is too large, the aspect ratio becomes high when filling the conductive film CF1. Therefore, the thickness of the base film BF1 is preferably smaller than the thickness of the interlayer dielectric film IL.

### Second Embodiment

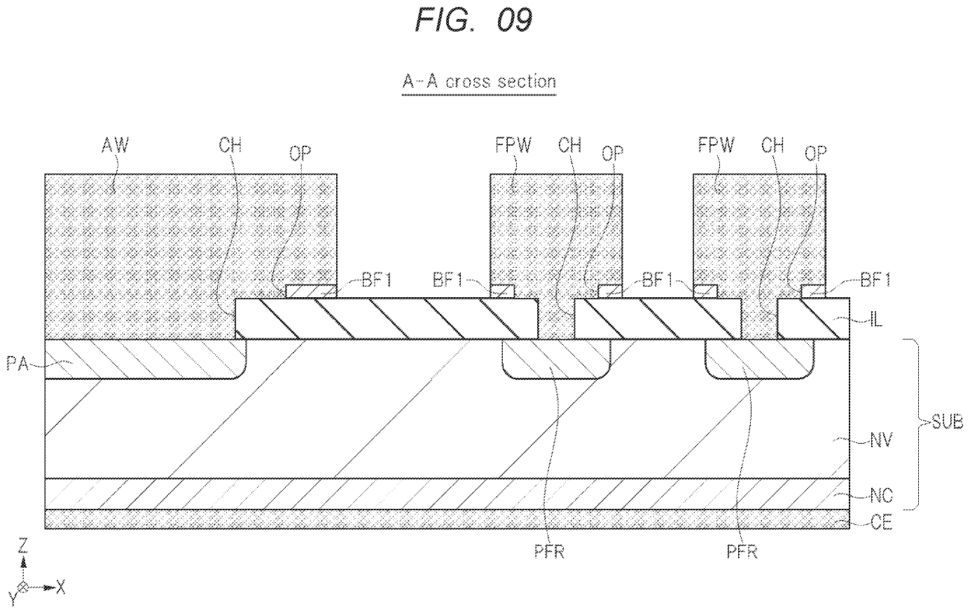

The semiconductor device 100 and its manufacturing method in the second embodiment will be described below with reference to FIG. 9 to FIG. 14. Note that, in the following description, differences from the first embodiment will be mainly described, and the description of overlapping points with the first embodiment will be omitted.

In the first embodiment, a hole CH is formed in the base film BF1 and the interlayer dielectric film IL. In the second embodiment, as shown in FIG. 9, the end portion of each of the anode wiring AW and the plurality of field plate wirings FPW is located on the base film BF1, but the base film BF1 has an opening OP wider than the opening of the hole CH. In other words, the opening OP includes the hole CH in plan view. That is, a plurality of holes CH are formed in the interlayer dielectric film IL so as to reach the semiconductor substrate SUB at a position not overlapping with the base film BF1 in plan view.

Therefore, when the conductive film CF1 is filled in the hole CH, the possibility that the filling defect of the conductive film CF1 occurs can be reduced because the aspect ratio is reduced by the thickness of the base film BF1.

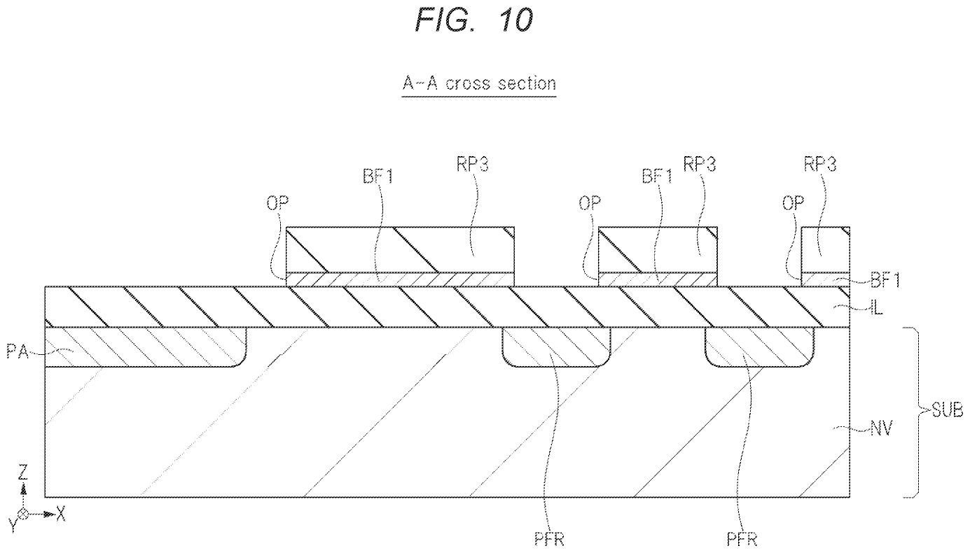

The manufacturing processes included in the manufacturing method of the semiconductor device 100 in the second embodiment will be described below with reference to FIG. 10 to FIG. 14. FIG. 10 shows a manufacturing process following FIG. 4 of the first embodiment.

As shown in FIG. 10, first, a resist pattern RP3 is formed on the base film BF1. Next, by performing an anisotropic etching process using the resist pattern RP3 as a mask, the base film BF1 is patterned. As a result, an opening OP is formed in the base film BF1. Thereafter, the resist pattern RP3 is removed by an ashing process.

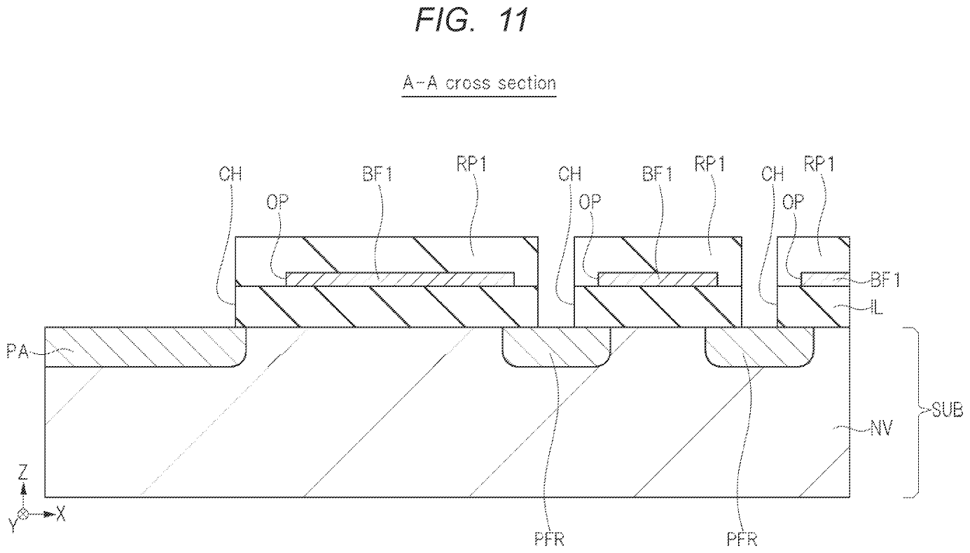

As shown in FIG. 11, first, a resist pattern RP1 is formed on the interlayer dielectric film IL. At this time, the resist pattern RP1 has a pattern that opens in the opening portion OP in plan view. Next, by performing an anisotropic etching process using the resist pattern RP1 as a mask, a plurality of holes CH reaching the semiconductor substrate SUB are formed in the interlayer dielectric film IL at a position not overlapping with the base film BF1 in plan view. In other words, the plurality of holes CH are formed in the interlayer dielectric film IL located in the opening portion OP. Thereafter, the resist pattern RP1 is removed by an ashing process.

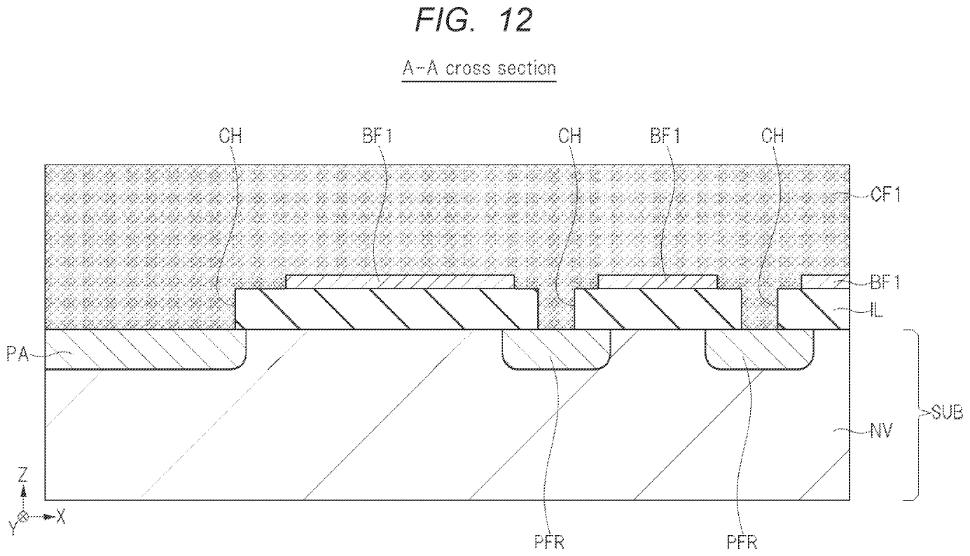

As shown in FIG. 12, the conductive film CF1 is formed on the base film BF1 and the interlayer dielectric film IL by a sputtering method so as to fill the insides of the plurality of holes CH. The conductive film CF1 is formed of the above-described aluminum alloy. As described above, in the second embodiment as compared with the first embodiment, since the aspect ratio is reduced, it is possible to reduce the possibility that the filling defect of the conductive film CF1 occurs.

As shown in FIG. 13, first, a resist pattern RP2 is formed on the conductive film CF1. Next, the conductive film CF1 is patterned by performing an anisotropic etching process using the resist pattern RP2 as a mask. As a result, a part of the conductive film CF1 is removed, an anode wiring AW is formed in the cell region CR, and a plurality of field plate wirings FPW are formed in the outer peripheral region OR. Here, the conductive film CF1 is patterned such that the end portion of each of the anode wiring AW and the plurality of field plate wirings FPW are located on the base film BF1.

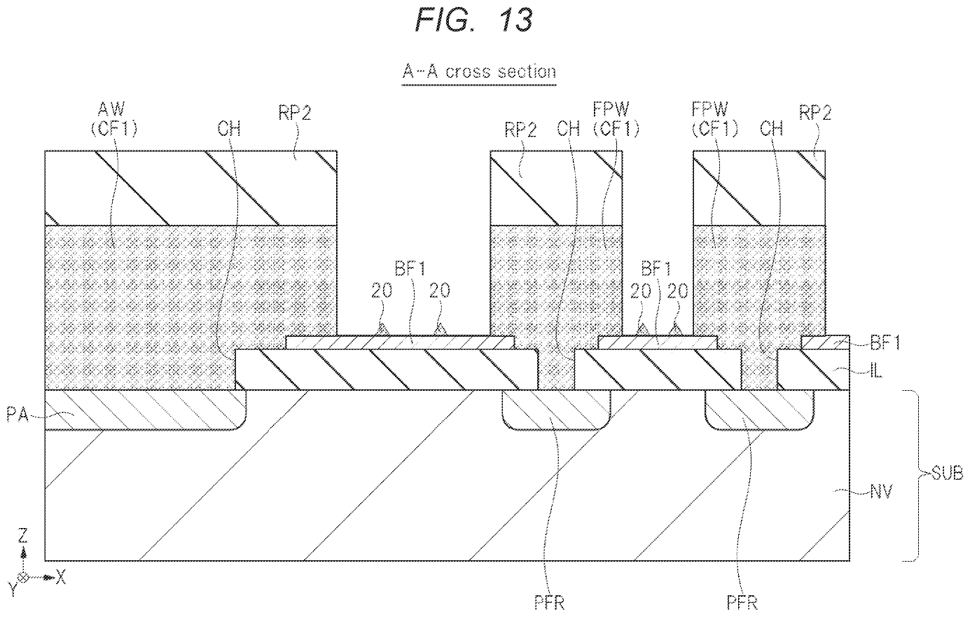

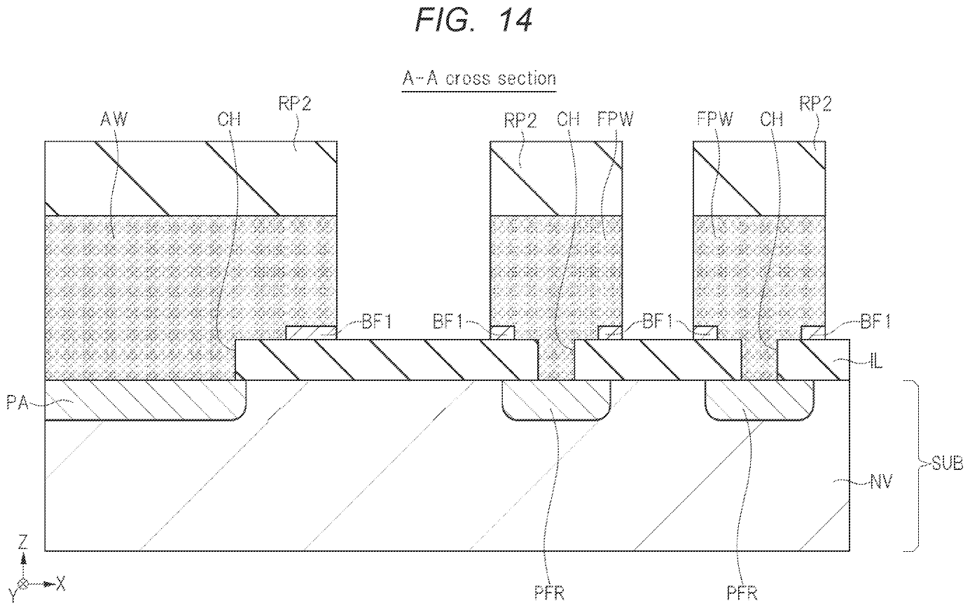

As shown in FIG. 14, by performing an isotropic etching process using the resist pattern RP2 as a mask, the base film BF1 located between the field plate wirings FPW and between the anode wiring AW and the field plate wiring FPW is removed. At this time, the residue 20 is removed together with the base film BF1. Thereafter, the resist pattern RP2 is removed by an asking process.

Thereafter, the cathode region NC and the cathode electrode CE are formed by a manufacturing process similar to that of the first embodiment, whereby the structure of FIG. 9 is obtained.

### Third Embodiment

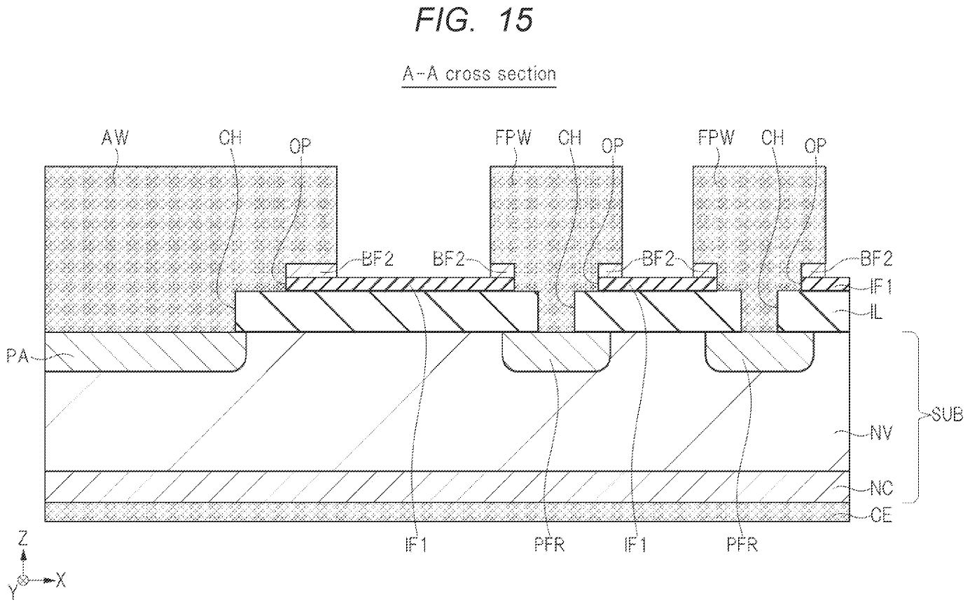

The semiconductor device 100 and its manufacturing method in the third embodiment will be described below with reference to FIG. 15 to FIG. 21. Note that, in the following description, differences from the first embodiment will be mainly described, and the description of overlapping points with the first embodiment will be omitted.

In the third embodiment, a protective film IF1 is selectively formed on the interlayer dielectric film IL, and a base film BF2 is selectively formed on the protective film IF1. In the base film BF2 and the protective film IF1, an opening portion OP wider than the opening of the hole CH is formed. In other words, the opening portion OP includes the hole CH in plan view. That is, a plurality of holes CH are formed in the interlayer dielectric film IL so as to reach the semiconductor substrate SUB at a position not overlapping with the protective film IF and the base film BF2 in plan view.

Therefore, when the conductive film CF1 is filled in the hole CH, the possibility that the filling defect of the conductive film CF1 occurs can be reduced because the aspect ratio is reduced by the thickness of each of the protective film IF1 and the base film BF2.

Further, although the end portion of each of the anode wiring AW and the plurality of field plate wirings FPW is located on the base film BF2, the base film BF2 may be entirely removed in the third embodiment. Therefore, it can be said that the above-described end portion is located on the protective film IF1.

The material constituting the base film BF2 is different from the material constituting each of the anode wiring AW and the plurality of field plate wirings FPW. The base film BF2 is, for example, a silicon oxide film. The thickness of the base film BF2 is smaller than the thickness of the interlayer dielectric film IL, for example, greater than or equal to 50 nm and less than or equal to 1000 nm.

The material constituting the protective film IF1 is different from the material constituting each of the anode wiring AW, the plurality of field plate wirings FPW, the base film BF2, and the interlayer dielectric film IL. The protective film IF1 is, for example, a silicon nitride film. The thickness of the protective film IF1 is smaller than the thickness of the interlayer dielectric film IL, for example, greater than or equal to 50 nm and less than or equal to 1000 nm.

The protective film IF1 covers the interlayer dielectric film IL located between the field plate wirings FPW and between the anode wiring AW and the field plate wiring FPW. However, the base film BF2 has been removed between these wirings.

The third embodiment is similar to the base film BF1 of the first embodiment and the second embodiment in that the base film BF2 is provided to remove the residue 20, but is different from the first embodiment in that the protective film IF1 covers the interlayer dielectric film IL located between the respective wiring.

### Comparison Between Third Embodiment and Second Examined Example and Third Examined Example

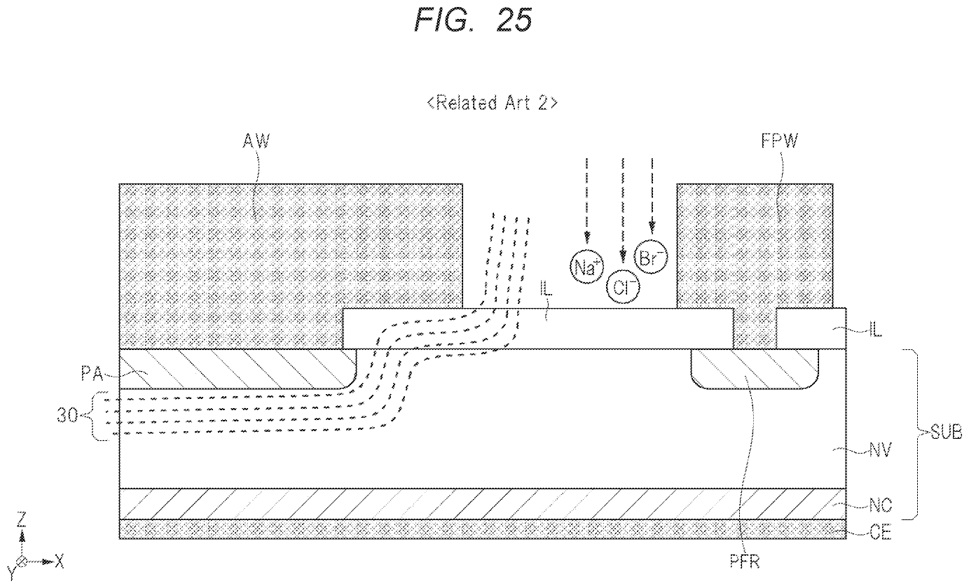

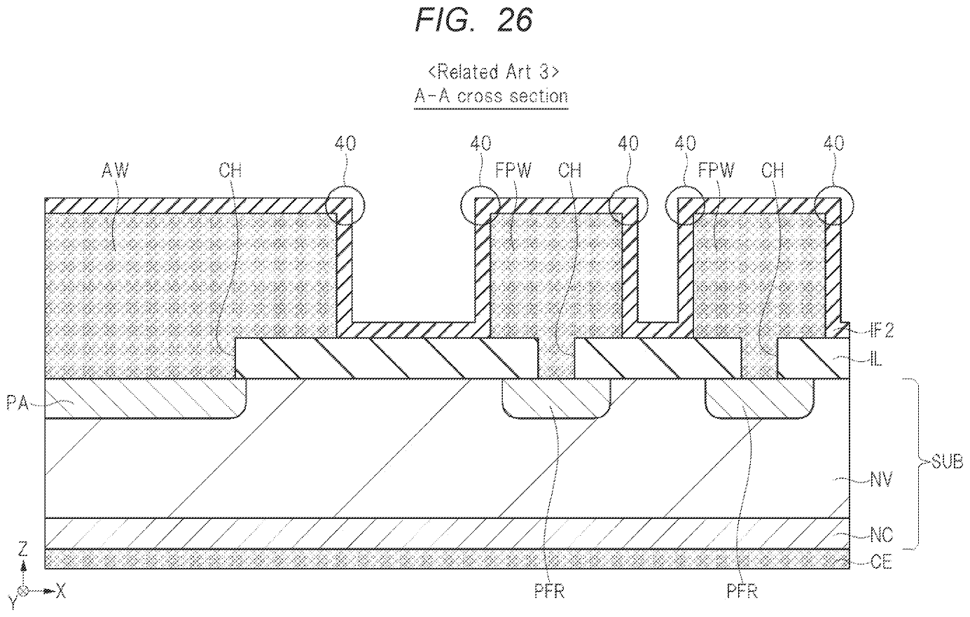

FIG. 25 and FIG. 26 show the semiconductor device of the second examined example and the third examined example studied by the present inventors.

In the second examined example shown in FIG. 25, a base film BF2 and a protective film IF1 such as third embodiment are not formed. The dashed line shown in FIG. 25 represents the equipotential line 30 when a reverse-bias is applied to the semiconductor device 100.

An electric field is concentrated near the end portion of each of the anode wiring AW and the plurality of field plate wirings FPW. Here, when the thickness of the interlayer dielectric film IL is reduced, the electric field is further concentrated at each end portions, and the withstand voltage is lowered. In the third embodiment, since the protective film IF1 which is a dielectric film is formed at the respective end portions, the electric field concentration can be reduced.

In addition, the semiconductor device 100 is covered with a resin in a back-end process. At this time, there is a possibility that an electrolyte solution containing ions such as Na⁺, Br⁻ or Cl⁻ may reach the interlayer dielectric film IL. As a result, the electric field generated in the interlayer dielectric film IL increases due to the ions, and the withstand voltage is more likely to decrease. In the third embodiment, since the interlayer dielectric film IL exposed from each wiring is covered with the protective film IF1, it is possible to suppress the entering of each ion. Therefore, the reliability of the semiconductor device 100 can be improved.

In the third examined example shown in FIG. 26, in order to solve the problem of the second examined example, a protective film IF2 is formed on the interlayer dielectric film IL so as to cover each wiring after each wiring is patterned. The protective film IF2 is formed of a silicon nitride film as in the case of the protective film IF1. Even in the protective film IF2 of the third examined example, it is possible to suppress the entering of ions. However, according to studies conducted by the inventors of the present application, it is found that, when the semiconductor device of the third examined example is subjected to a thermal cycling test, cracks easily occur in the protective film IF2 at the upper portions of the respective wiring. In FIG. 26, such locations are shown as crack generation locations 40. Such a crack may be determined as a defect in appearance abnormality, and may serve as an entering path of moisture from the outside.

In the third embodiment, since the protective film IF1 covers only the interlayer dielectric film IL, the above-described cracks do not occur.

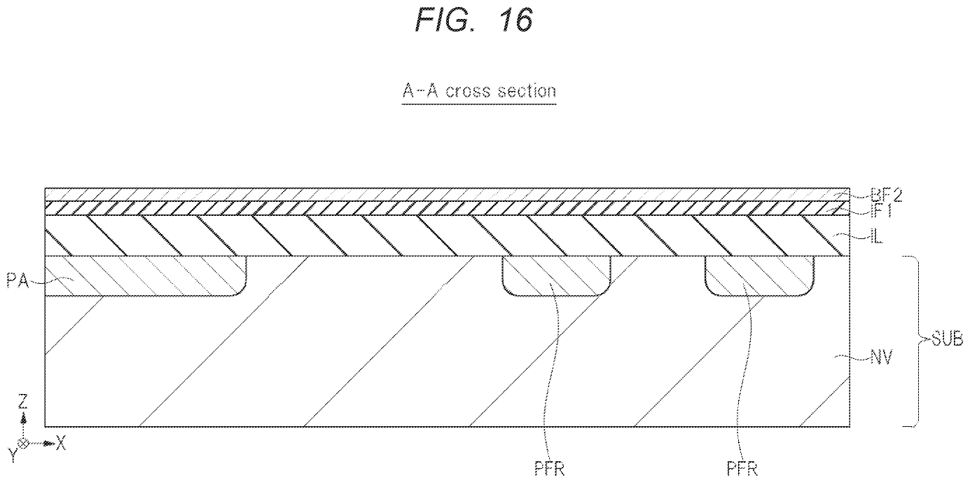

The manufacturing processes included in the manufacturing method of the semiconductor device 100 in the third embodiment will be described below with reference to FIG. 16 to FIG. 21. FIG. 16 shows a manufacturing process following FIG. 3 of the first embodiment.

As shown in FIG. 16, first, an interlayer dielectric film IL is formed on the upper surface of the semiconductor substrate SUB in the cell region CR and the outer peripheral region OR by, for example, a CVD method. Next, a protective film IF1 is formed on the interlayer dielectric film IL by, for example, a CVD method. Next, a base film BF2 is formed on the protective film IF1 by, for example, a CVD method.

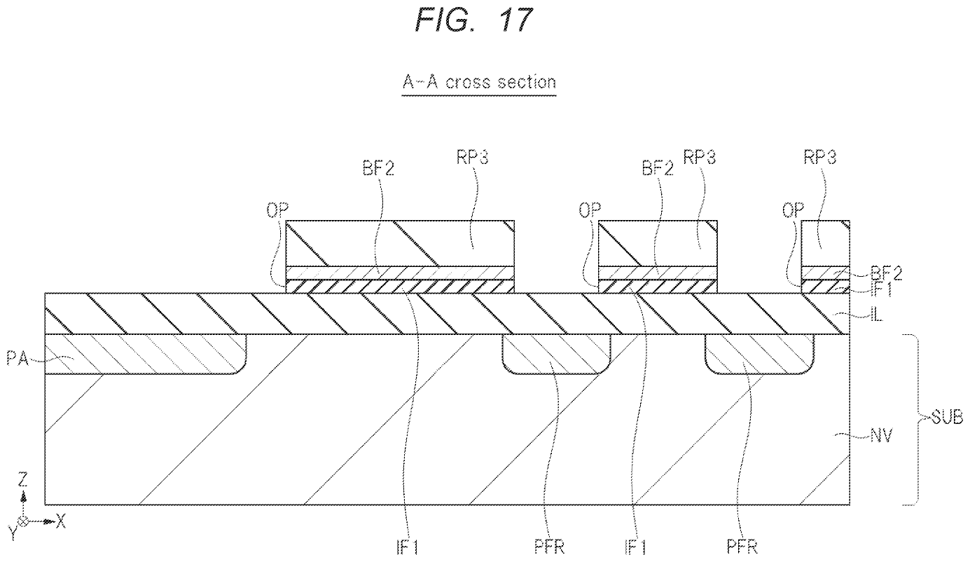

As shown in FIG. 17, first, a resist pattern RP3 is formed on the base film BF1. Next, by performing an anisotropic etching process using the resist pattern RP3 as a mask, the base film BF2 and the protective film IF1 are patterned. As a result, an opening portion OP is formed in the base film BF2 and the protective film IF1. Thereafter, the resist pattern RP3 is removed by an ashing process.

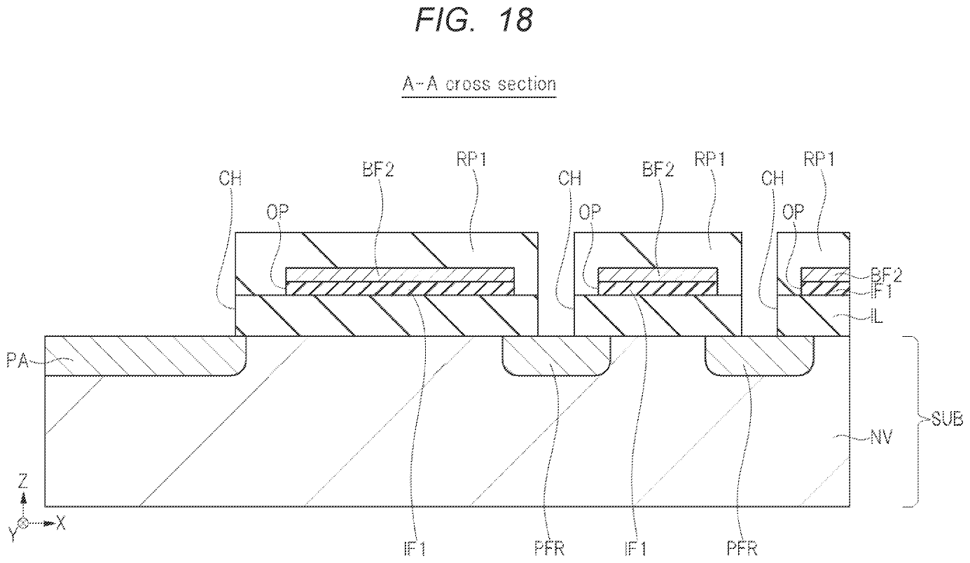

As shown in FIG. 18, first, a resist pattern RP1 is formed on the interlayer dielectric film IL. At this time, the resist pattern RP1 has a pattern that opens in the opening portion OP in plan view. Next, by performing an anisotropic etching process using the resist pattern RP1 as a mask, a plurality of holes CH reaching the semiconductor substrate SUB are formed in the interlayer dielectric film IL at a position not overlapping the base film BF2 and the protective film IF1 in plan view. In other words, the plurality of holes CH are formed in the interlayer dielectric film IL located in the opening portion OP. Thereafter, the resist pattern RP1 is removed by an ashing process.

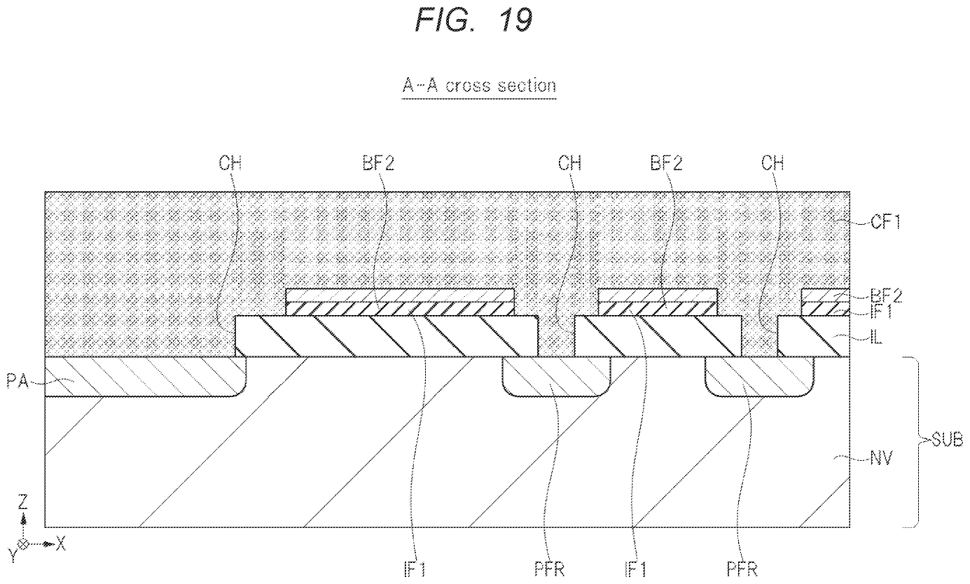

As shown in FIG. 19, the conductive film CF1 is formed on the base film BF2 and the interlayer dielectric film IL by a sputtering method so as to fill the insides of the plurality of holes CH. The conductive film CF1 is formed of the above-described aluminum alloy. As described above, in the third embodiment as compared with the first embodiment, since the aspect ratio is reduced, it is possible to reduce the possibility that the filling defect of the conductive film CF1 occurs.

From the viewpoint of reducing the aspect ratio at the time of filling the conductive film CF1 as much as possible, the thickness of each of the base film BF2 and the protective film IF1 is preferably smaller than the thickness of the interlayer dielectric film IL.

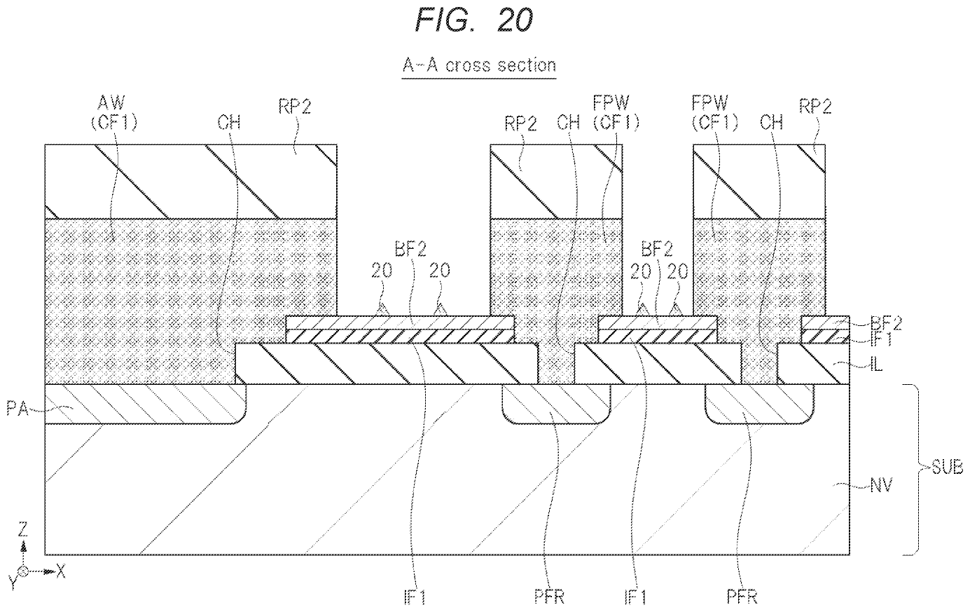

As shown in FIG. 20, first, a resist pattern RP2 is formed on the conductive film CF1. Next, the conductive film CF1 is patterned by performing an anisotropic etching process using the resist pattern RP2 as a mask. As a result, a part of the conductive film CF1 is removed, the anode wiring AW is formed in the cell region CR, and the plurality of field plate wirings FPW are formed in the outer peripheral region OR. Here, the conductive film CF1 is patterned such that the end portion of each of the anode wiring AW and the plurality of field plate wirings FPW are located on the base film BF2.

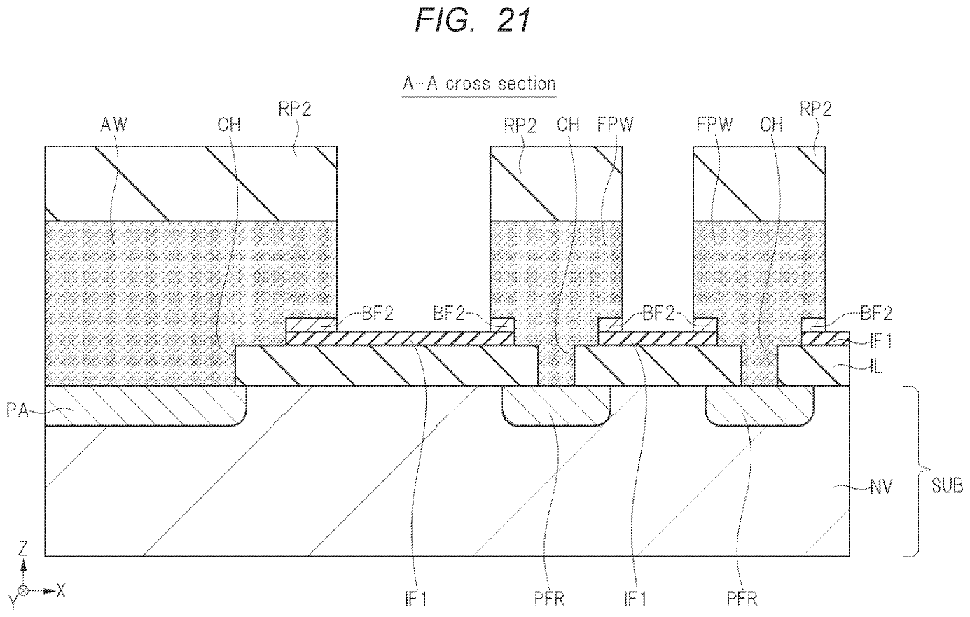

As shown in FIG. 21, by performing an isotropic etching process using the resist pattern RP2 as a mask, the base film BF1 located between the field plate wirings FPW and between the anode wiring AW and the field plate wiring FPW is removed. At this time, the residue 20 is removed together with the base film BF2. Thereafter, the resist pattern RP2 is removed by an asking process. After the manufacturing process of FIG. 21, a protective film IF1 is left between the field plate wirings FPW and between the anode wiring AW and the field plate wiring FPW.

Here, it is exemplified that the base film BF2 is left between wiring and the protective film IF1, but the base film BF2 may be entirely removed by the isotropic etching process.

Thereafter, the cathode region NC and the cathode electrode CE are formed by a manufacturing process similar to that of the first embodiment, whereby the structure of FIG. 15 is obtained.

Although the present invention has been described in detail based on embodiments, the present invention is not limited to the above-described embodiments, and various modifications can be made without departing from the gist of the present invention.

For example, although a diode is exemplified as a semiconductor element formed in the cell region CR in the above embodiment, the semiconductor element may be another element such as an IGBT or a MOSFET.

What is claimed is:

1. A method of manufacturing a semiconductor device, the method comprising:
(a) preparing a semiconductor substrate of a first conductivity type, the semiconductor substrate having an upper surface and a lower surface;
(b) after the (a), forming an interlayer dielectric film on the upper surface of the semiconductor substrate;
(c) after the (b), forming a base film on the interlayer dielectric film;
(d) after the (c), forming a first conductive film on the base film;
(e) after the (d), patterning the first conductive film to form a first wiring and a second wiring next to the first wiring; and
(f) after the (e), removing the base film located between the first wiring and the second wiring,
wherein a material constituting the base film is different from a material constituting the first conductive film.

2. The method according to claim 1, comprising:
(g) between the (c) and the (d), forming a plurality of holes reaching the semiconductor substrate in the base film and the interlayer dielectric film,
wherein in the (d), the first conductive film is formed so as to fill the insides of the plurality of holes.

3. The method according to claim 1, comprising:
(h) between the (c) and the (d), patterning the base film,
wherein in the (d), the first conductive film is formed on the base film and the interlayer dielectric film, and
wherein in the (e), the first conductive film is patterned such that an end portion of the first wiring and an end portion of the second wiring are located on the base film.

4. The method according to claim 3, comprising:
(i) between the (h) and the (d), forming a plurality of holes reaching the semiconductor substrate in the interlayer dielectric film at a position not overlapping with the base film in plan view, and
wherein in the (d), the first conductive film is formed so as to fill the insides of the plurality of holes.

5. The method according to claim 3, comprising:
(j) between the (b) and the (c), forming a protective film on the interlayer dielectric film,
wherein in the (c), the base film is formed on the protective film,
wherein in the (h), the protective film is patterned,
wherein after the (f), the protective film is left between the first wiring and the second wiring, and
wherein a material constituting the protective film is different from a material constituting each of the base film and the first conductive film.

6. The method according to claim 5, comprising:
(k) between the (h) and the (d), forming a plurality of holes reaching the semiconductor substrate in the interlayer dielectric film at a position not overlapping with the base film and the protective film in plan view, and
wherein in the (d), the first conductive film is formed so as to fill the insides of the plurality of holes.

7. The method according to claim 1,
wherein the first conductive film is formed of an aluminum alloy that an additive is added to aluminum,
wherein the additive is silicon or copper, or both,
wherein the base film is a polycrystalline silicon film or a silicon nitride film, and
wherein the interlayer dielectric film in contact with the base film is a silicon oxide film.

8. The method according to claim 5,
wherein the first conductive film is formed of an aluminum alloy that an additive is added to aluminum,
wherein the additive is silicon or copper, or both,
wherein the base film is a silicon oxide film,
wherein the protective film is a silicon nitride film, and
wherein the interlayer dielectric film in contact with the protective film is a silicon oxide film.

9. The method according to claim 1,
wherein in the (e), a part of the first conductive film is removed by an anisotropic etching process.

10. The method according to claim 1,
wherein in the (f), the base film is removed by an isotropic etching process.

11. The method according to claim 1,
wherein a thickness of the base film is smaller than a thickness of the interlayer dielectric film.

12. The method according to claim 3,
wherein in the (e), the first conductive film is patterned to form a third wiring,
wherein the third wiring is an anode wiring connected to an anode region of a diode provided in the semiconductor substrate,
wherein, in plan view, the first wiring is formed so as to surround the third wiring, and
wherein, in plan view, the second wiring is formed so as to surround the third wiring and the first wiring.

13. The method according to claim 1,
wherein after the (e), a precipitate formed of the material constituting the first conductive film is formed on the base film located between the first wiring and the second wiring, and
wherein in the (f), the precipitate is removed by removing the base film located between the first wiring and the second wiring.

14. A semiconductor device comprising:
a semiconductor substrate of a first conductivity type, the semiconductor substrate having an upper surface and a lower surface,
an interlayer dielectric film formed on the upper surface of the semiconductor substrate,
a protective film selectively formed on the interlayer dielectric film,
a first hole and a second hole each formed in the interlayer dielectric film so as to reach the semiconductor substrate at a position not overlapping with the protective film in plan view,
a first wiring formed on the interlayer dielectric film and the protective film so as to fill the inside of the first hole, and
a second wiring formed on the interlayer dielectric film and the protective film so as to fill the inside of the second hole, the second wiring being next to the first wiring,
wherein an end portion of the first wiring and an end portion of the second wiring are located on the protective film,
wherein the protective film covers the interlayer dielectric film located between the first wiring and the second wiring, and
wherein a material constituting the protective film is different from a material constituting each of the first wiring, the second wiring and the interlayer dielectric film.

15. The semiconductor device according to claim 14,
wherein a base film is formed between the protective film and the first wiring and between the protective film and the second wiring, and
wherein the first hole and the second hole are formed in the interlayer dielectric film at a position not overlapping with the base film in plan view.

16. The semiconductor device according to claim 14,
wherein the first wiring and the second wiring are each formed of an aluminum alloy that an additive is added to aluminum,
wherein the additive is silicon or copper, or both,
wherein the protective film is a silicon nitride film, and
wherein the interlayer dielectric film in contact with the protective film is a silicon oxide film.

17. The semiconductor device according to claim 14,
wherein a thickness of the protective film is smaller than a thickness of the interlayer dielectric film.

18. The semiconductor device according to claim 14, comprising:
a cell region in which a semiconductor element is formed, and
an outer peripheral region surrounding the cell region in plan view,
wherein an anode region of a second conductivity type opposite the first conductivity type is formed in the semiconductor substrate in the cell region on the upper surface side of the semiconductor substrate,
wherein a cathode region of the first conductivity type is formed in the semiconductor substrate in the cell region on the lower surface side of the semiconductor substrate,
wherein a cathode electrode is formed on the lower surface of the semiconductor substrate,
wherein a field limiting region of the second conductivity type is formed in the semiconductor substrate in the outer peripheral region on the upper surface side of the semiconductor substrate,
wherein the first hole reaches the anode region,
wherein the second hole reaches the field limiting region,
wherein the first wiring is formed in the cell region and is electrically connected to the anode region,
wherein the second wiring is formed in the outer peripheral region and is electrically connected to the field limiting region, and
wherein the second wiring and the field limiting region are formed so as to surround the cell region in plan view and in an electrically floating state.

19. The semiconductor device according to claim 14, comprising:
a cell region in which a semiconductor element is formed, and
an outer peripheral region surrounding the cell region in plan view,
wherein a first field limiting region of a second conductivity type opposite the first conductivity type and a second field limiting region of the second conductivity type are formed in the semiconductor substrate in the outer peripheral region on the upper surface side of the semiconductor substrate,
wherein the first hole reaches the first field limiting region,
wherein the second hole reaches the second field limiting region,
wherein the first wiring is formed in the outer peripheral region and is electrically connected to the first filed limiting region,
wherein the second wiring is formed in the outer peripheral region and is electrically connected to the second filed limiting region,
wherein the first wiring and the first field limiting region are formed so as to surround the cell region in plan view and in an electrically floating state, and
wherein the second wiring and the second field limiting region are formed so as to surround the first wiring and the first field limiting region in plan view and in an electrically floating state.
